(19) United States
(12) Patent Application Publication
(10) Pub. No.: US 2002/0051353 A1
(43) Pub. Date: May 2, 2002

(54) High-frequency ceramic package

(75) Inventor: Akiyoshi Osakada, Mine-shi (JP)

Correspondence Address: ARMSTRONG,WESTERMAN & HATTORI, LLP, 1725 K STREET, NW., SUITE 1000, WASHINGTON, DC, 20006, US

(73) Assignee: Sumitomo Metal (SMI) Electronics Devices Inc., Mine-shi (JP)

(21) Appl. No.: 09/845,327

(22) Filed: May 1, 2001

(30) Foreign Application Priority Data
Sep. 20, 2000 (JP) 2000-285449

(51) Int. Cl. H05K 7/00

(52) U.S. Cl. 361/820

(57) ABSTRACT

A high-frequency ceramic package 10 comprises a ceramic frame plate 12 brazed to a jointed metal plate 11 on the surface thereof, the jointed metal plate 11 including a substantially rectangular shaped first metal plate 17 which has a hollowed portion 19 at a central portion thereof and a second metal plate 18 which is fitted in the hollowed portion 19 in a state in which the first and second metal plate 17, 18 are jointed together in end-to-end relationship. The first metal 17 is close to the ceramic frame plate in thermal expansion coefficient, and the second metal plate 18 is made from a material having a high level of heat-sinking characteristics. A concave cavity 16 defined between the second metal plate 18 and the ceramic frame plate 12 has a semiconductor electronic component mounting portion on a bottom 16a of the cavity 16.

### BACKGROUND OF THE INVENTION

This invention relates to a high-frequency ceramic package. More particularly, it relates to an improved high-frequency ceramic package having a ceramic frame plate brazed to a jointed metal plate, the jointed metal plate including two kinds of metal plates jointed together.

A prior art high-frequency ceramic package that is formed by a ceramic frame plate brazed to a metal plate is designed to protect electrical characteristics, in a high-frequency range of semiconductor electronic components, against heat that is given off from the semiconductor electronic components. More specifically, the semiconductor electronic components are disposed on a substantially rectangular-shaped metal plate that is made from highly heat-sinking material, in order to provide enhanced heat-sinking characteristics. Meanwhile, the high-frequency ceramic package is formed by ceramics jointed to the metal plate. In this instance, one material that forms the ceramics is close in thermal expansion coefficient to another material that forms the metal plate in order to reduce a difference between respective amounts of thermal expansion of the ceramics and metal plate, which is caused by rises in temperatures of the ceramics and metal plate. This structure avoids developing a curl in the ceramic package, and thus the semiconductor electronic components do not detract from their functions. FIGS. 4(A) and 4(B) illustrate a prior art high-frequency ceramic package 50 by way of one example. A ceramic frame plate 52 is bonded to a metal plate 51 through a metallized pattern by means of a silver/copper solder 54. The metal plate 51 is made from Cu—W (porous, copper-impregnated tungsten), which is close to ceramics in thermal expansion coefficient, and further which provides better heat-sinking characteristics. The metallized pattern is formed on the ceramic frame plate 52 on the reverse side thereof. In addition, leads 55 for connection to the outside are brazed to the ceramic frame plate 52 through a metallized pattern 53 by means of the silver/copper solder. The metallized pattern 53 is formed on the ceramic frame plate 52 on the obverse side thereof. The metal plate 51, the ceramic frame plate 52, and the leads 55 brazed together by means of the silver/copper solder are then nickel-plated and gold-plated on metal surfaces thereof, thereby forming the high-frequency ceramic package 50. The substantially rectangular-shaped metal plate 51 is provided with fixing cutouts 56 at both ends of the metal plate 51 in a longitudinal direction thereof for fixing the ceramic package 50. The metal plate 51 is screwed down tight on a fixing member at the cutouts 56. In the ceramic package 50, the semiconductor electronic components are packaged on the metal plate 51 at a position where the metal plate 51 is exposed inside the ceramic frame plate 52. The packaged semiconductor components are then sealed in a hermetic sealing manner by means of resin.

However, the prior art high-frequency ceramic package as previously described presents problems as given below:

(1) In a trend of the semiconductor electronic components toward higher frequencies, there has been an eager demand for a further heat-sinking level in order to avoid deteriorating electrical characteristics in a high-frequency range of the semiconductor electronic components. However, when a highly heat-sinking metal plate having an increased level of thermal conductivity, e.g., a heat-sinking material made of a copper alloy, is employed, then such a heat-sinking material provides a proportionally increased level of a thermal expansion coefficient. More specifically, the copper alloy has a thermal expansion coefficient of some 18.5×10⁻⁶/K, which is substantially greater than a ceramic thermal expansion coefficient of about 6.7×10⁻⁶/K. Accordingly, such a difference in thermal expansion coefficient between the metal plate and the ceramics results in a difference in amounts of thermal expansion between these two components. This phenomenon produces an increased curl in the high-frequency ceramic package. As a result, there are cases where the semiconductor electronic components cannot be packaged on the metal plate.

(2) The increased curl in the ceramic package causes a distortion-caused bend in the ceramic package. Such a bend brings about another problem in which the semiconductor electronic components on the metal plate are destroyed when the ceramic package is mounted on the fixing member.

An object of the present invention is to provide a high-frequency ceramic package, adapted for an additional heat-sinking level of such a ceramic package and further for a decrease in the occurrence of a curl.

### SUMMARY OF THE INVENTION

The present invention provides a high-frequency ceramic package, including a ceramic frame plate brazed to a jointed metal plate on a surface of the jointed metal plate, the jointed metal plate including first and second metal plates in which the first metal plate forms a substantially rectangular shape, the first metal plate having fixing cutouts defined at both ends of the first metal plate in a longitudinal direction thereof, the first metal plate further having a hollowed portion formed at a central portion thereof, while the second metal plate is fitted in the hollowed portion of the first metal plate in a state in which the first and second metal plates are jointed together in an end-to-end relationship, thereby forming the jointed metal plate, the improvement wherein one material that forms the first metal plate differs in thermal expansion coefficient from another material that forms the second metal plate; a concave cavity defined between the second metal plate and the ceramic frame plate has a semiconductor electronic component mounting portion disposed on a bottom of the cavity; and, the second metal plate is made from a material having a high degree of heat-sinking characteristics.

Since the jointed metal plate to be brazed to the ceramic frame plate includes two different kinds of metals, or rather the first and second metal plates, the first metal plate can be made from a material close to the ceramic frame plate in thermal expansion coefficient. As a consequence, the jointed metal plate provides a reduced curl, even when the ceramic frame plate is jointed to the first metal plate. In addition, the second metal plate, which forms a portion where the semiconductor electronic components are disposed, can be made of a highly heat-sinking metal plate that has a high degree of thermal conductivity. As a result, the high-frequency ceramic package according to the present invention is allowed to provide a high level of cooling effects, and thus to maintain electrical characteristics under the circumstances in which the semiconductor electronic components have higher frequencies prevail.

The ceramic frame plate may be brazed to the first and second metal plates in a state of being disposed across respective surfaces of the first and second metal plates along a position where the first and second metal plates are jointed together. Consequently, even when one of the first and second metal plates differs from the ceramic frame plate in thermal expansion coefficient, then the other of the first and second metal plates can be made from a material close to the ceramic frame plate in thermal expansion coefficient in order to mitigate the occurrence of the curl. As a result, a reduced curl occurs in the jointed metal plate. Moreover, since the ceramic frame plate is brazed across the respective surfaces of the first and second metal plates, the first and second metal plates can be jointed together with increased strength and hermetic sealing.

As an alternative, the ceramic frame plate may be brazed to the first metal plate. In this instance, the first metal plate is made from a material close to the ceramic frame plate in thermal expansion coefficient. As a result, a curl in the jointed metal plate is reduced. In this connection, even when the second metal plate is greater in thermal expansion coefficient than the first metal plate, such a difference in thermal expansion coefficient is unrelated to an increase in the curl because the second metal plate is not connected directly to the ceramic frame plate.

The first metal plate may be made from either KV or a 42 alloy, both of which are close to ceramics in thermal expansion coefficient, while the second metal plate may be formed by a highly heat-sinking material that is made from a compound material. The compound material includes copper and other metals. As a result, even when the ceramic frame plate is brazed to such a jointed metal plate, a curl can be restrained from occurring in the jointed metal plate. Furthermore, the above-described jointed metal plate structure is able to ensure a heat-sinking material adapted to accommodate high heat radiation from the semiconductor electronic components.

### BRIEF DESCRIPTION OF THE DRAWINGS

FIG. 1 is a perspective view, illustrating a high-frequency ceramic package according to an embodiment of the present invention;

FIG. 2(A) is a front view, illustrating a jointed metal plate of the ceramic package;

FIG. 2(B) is a cross-sectional view on line B-B in FIG. 2(A), illustrating the jointed metal plate;

FIG. 3(A) is an enlarged partial cross-sectional view on line A-A in FIG. 1;

FIG. 3(B) is an enlarged partial cross-sectional view according to another embodiment of the present invention;

FIG. 4(A) is a plan view, showing a prior art high-frequency ceramic package; and,

FIG. 4(B) is a front view, showing the prior art ceramic package.

### DETAILED DESCRIPTION OF THE PREFERRED EMBODIMENT

An embodiment that embodies the present invention will now be described with reference to the accompanying drawings for a more complete understanding of the present invention.

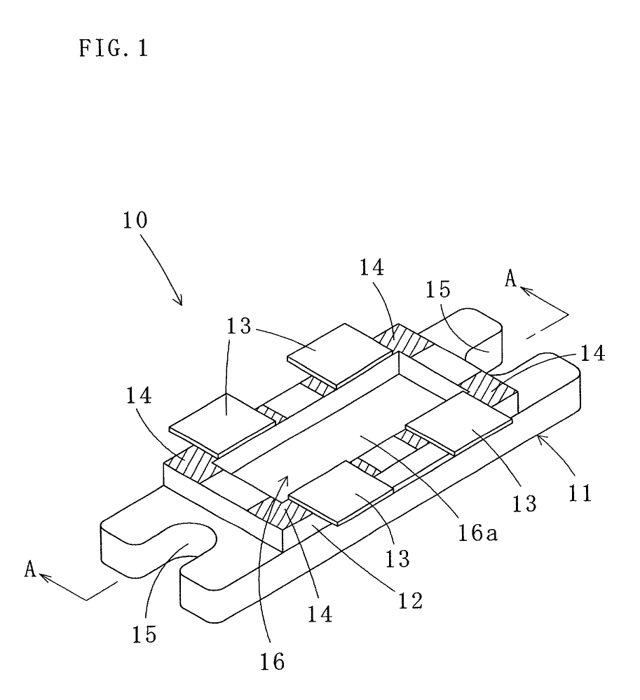

An initial description will now be made of how a high-frequency ceramic package 10 according to the embodiment is constructed. FIG. 1 illustrates a ceramic frame plate 12 brazed or jointed at the reverse side thereof to a jointed metal plate 11 by means of, e.g., a silver/copper solder. In addition, leads 13 for connection to the outside are brazed to the ceramic frame plate 12 through metallized patterns 14 by means of, e.g., the sliver/copper solder. The metallized patterns 14 are formed on the ceramic frame plate 12 on the obverse side thereof. The lead 13 is formed by either KV (a Fe—Ni—Co series alloy, called “Koval” as a brand name) or a 42-alloy (a Ni—Fe alloy). Then, the brazed metal plate 11, ceramic frame plate 12, and leads 13 are nickel-plated and gold-plated on metal surfaces thereof, thereby forming the ceramic package 10. The substantially rectangular-shaped metal plate 11 is provided with fixing cutouts 15 at both ends of the metal plate 11 in a longitudinal direction thereof for fixing the ceramic package 10. The metal plate 11 is screwed down tight on a fixing member (not shown) at the cutouts 15. In the ceramic package 10, semiconductor electronic components are packaged in a concave cavity 16 on a bottom 16a thereof. The ceramic frame plate 12 has a hollow portion at the central portion thereof. The cavity 16 is defined between the jointed metal plate 11 and the ceramic frame plate 12. Namely, a semiconductor electronic component mounting portion is formed on the bottom 16a of the cavity 16. The packaged semiconductor components are then hermetically sealed by means of resin. A metal material that forms the bottom 16a is made from a highly heat-sinking material having a high level of thermal conductivity. Such a heat-sinking material includes, e.g., Cu—W (copper-soaked tungsten) and CMC (a jointed plate having three layers of Cu—Mo—Cu). Meanwhile, a low thermal expansion material close to ceramics in thermal expansion coefficient, such as KV and the 42-alloy, forms a peripherally extending metal portion around the bottom 16a, which supports the bottom 16a.

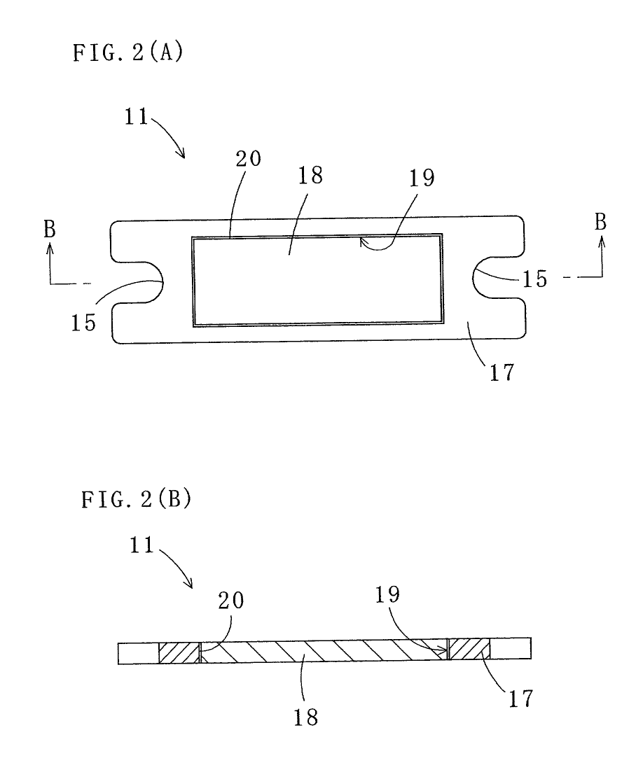

Then, a structure of the jointed metal plate 11 will now be described. As illustrated in FIGS. 2(A) and 2(B), the jointed metal plate 11 includes first and second metal plates 17, 18. The first metal plate 17 forms a substantially rectangular shape. The first metal plate 17 has the cutouts 15 formed at both ends of the plate 17 in the longitudinal direction thereof, and further has a hollowed portion 19 defined at a central portion of the first metal plate 17. The second metal plate 18 is fitted in the hollowed portion 19, while the hollowed portion 19 has end surfaces brazed or jointed to outer peripheral end surfaces of the second plate 18 by means of, e.g., a silver/copper solder 20. Hence, the thickness of the first metal plate 17 is as substantially same as that of the second metal plate 18. The first and second metal plates 17, 18 are made from metal materials that differ from one another in both thermal expansion coefficient and thermal conductivity. The first metal plate 17 is fabricated from a low thermal expansion material that is close to ceramics in thermal expansion coefficient. The ceramic frame plate 12 surrounds the cavity 16. The second plate 18 forms the bottom 16a, on which the semiconductor electronic components are disposed. The second plate 18 is formed by a metal material having a high degree of heat-sinking characteristics in which the second plate 18 is higher in thermal conductivity than the first metal plate 17. Such a metal structure is able to meet a demand for a high level of heat sinking, which is created in response to a trend of the semiconductor electronic components toward higher frequencies, and thus to maintain high-frequency characteristics.

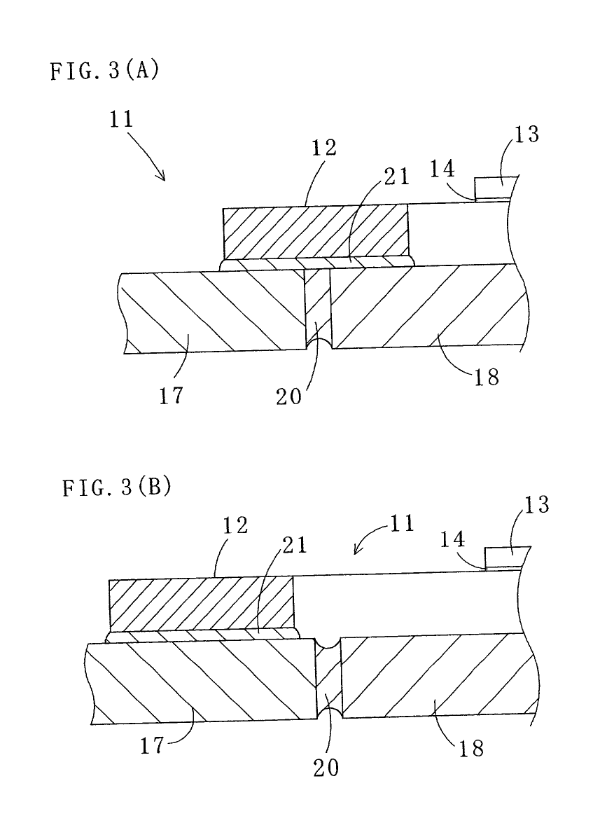

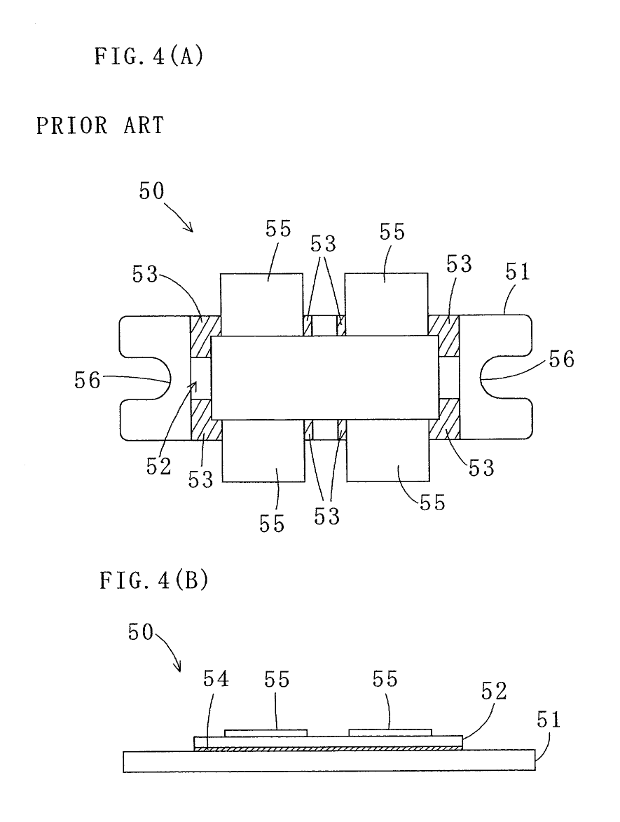

A further description will be given of how the ceramic plate 12 is jointed to the jointed metal plate 11 that includes the first and second metal plates 17, 18. As depicted in FIG. 3(A), the ceramic frame plate 12 is preferably brazed or jointed to the first and second metal plates 17, 18 by means of, e.g., a silver/copper solder 21 in a state in which the ceramic plate 12 extends along a position where the first and second metal plates 17, 18 are jointed together, and further which the ceramic plate 12 is disposed across respective surfaces of the first and second metals 17, 18 so as to cover the position where the metal plates 17, 18 are jointed together. At this time, the ceramic plate 12 may be brazed by means of the solder 21 after the first and second metal plates 17, 18 are jointed together by means of the silver/copper solder 20. Alternatively, the first and second metal plates 17, 18 and the ceramic plate 12 are jointed together at one time by means of the solders 20, 21. The ceramic plate 12 thus bonded to the metal plates 17, 18 across the respective surfaces thereof through the solder 21 provides good bonding between the metal plates 17, 18 and enhanced hermetic sealing reliability, even when the solder 20 is deficient in structural bond integrity between the metal plates 17, 18. Furthermore, efficient brazing is realized by simultaneous bonding of the metal plates 17, 18 and the ceramic plate 12 together through the solders 20, 21.

FIG. 3(B) depicts an alternative in which the ceramic plate 12 may be jointed to the first metal plate 17 through the solder 21. This structure is possible to restrain the occurrence of a curl in the ceramic package 10, which otherwise would be caused by a difference in thermal expansion coefficient, because the first metal plate 17 is close to ceramics in thermal expansion coefficient. The ceramic plate 12 may be brazed to the first metal plate 17 by means of the solder 21 after the first and second metal plates 17, 18 are initially jointed together by means of the solder 20. Alternatively, the ceramic plate 12 may be jointed to the first metal plate 17 through the solder 21, while the first and second metal plates 17, 18 are jointed together through the solder 20. Furthermore, efficient brazing is achievable when the metal plates 17, 18 and the ceramic plate 12 are jointed together at one time through the solders 20, 21.

Since the ceramic plate 12 is jointed to the first metal plate 17, it is preferable that the first plate 17 is close to ceramics in thermal expansion coefficient. Thus, KV and the 42-alloy, both of which are low in cost, are suitable as a material of the first metal plate 17. In this connection, alumina (Al₂O₃) has a thermal expansion coefficient of 6.7×10⁻⁶/K, while KV has that of 5.3×10⁻⁶/K. In order to maintain electrical characteristics under the circumstances in which the semiconductor electronic components have higher frequencies prevail, the second metal plate 18 must highly be operative to abate heat that radiates from the semiconductor electronic components. This means that the second metal plate 18 is required to provide a high level of heat-sinking ability, and thus to enhance cooling effectiveness. Thus, it is wise to use a compound material in which a highly heat-sinking material or copper is based. For example, the second metal plate 18 is preferably made of a CMC substrate having three layers of Cu—Mo—Cu jointed together at a thickness ratio of 1:1:1. In this connection, CMC has thermal conductivity of 260 W/m·K, while Cu—W has that of nearly 230 W/m·K.

The ceramic frame plate 12 is formed by the steps of: screen-printing a metallized pattern on a ceramic green sheet, in which the metallized pattern is made from a metal having a high melting point, such as tungsten; punching the ceramic green sheet to a ring-like shape; and, firing the sheet in a reducing atmosphere of a some 1550° C. In this connection, the ceramic green sheet is produced by the steps of: adding a plasticizer such as dioxyl phthalate, a binder such as acrylic resin, and a solvent such as toluene, xylene, and alcohol to powder in which a sintering assistant such as magnesia (MgO), silica (SiO₂), and calsia (CaO) is added in a proper amount to alumina powder; fully kneading the above materials, thereby creating a slurry having a viscosity that ranges from 2000 to 40000 cps after defoaming of the kneaded powder; forming the slurry into a roll-like ceramic green sheet by means of a doctor blade process; and, cutting the ceramic green sheet into rectangular pieces, each of which has an appropriate size. In order to provide the ceramic frame plate 12 having a required height, the ceramic green sheet is sometimes formed by a plurality of ceramic green sheets being laminated. In this connection, ceramics such as, e.g., alumina, aluminum nitride, and lower temperature fired glass ceramics are usable.

### EXAMPLE

The Inventor examined the high-frequency ceramic package according to the present invention in order to evaluate a thermal resistance value, the occurrence of a curl, and cost. The thermal resistance value exhibits heat-sinking characteristics of a jointed metal plate, and decreases with an increase in heat sinking. A ceramic frame plate bonded to the jointed metal plate by means of a silver/copper solder was a 10 mm wide, 22 mm long, and 1.0 mm thick rectangular frame of alumina ceramics, which was in the form of a ring having a width of 1.2 mm. The jointed metal plate was 10 mm wide, 34 mm long, and 1.6 mm thick. In the jointed metal plate, first and second metal plates were made from KV and CMC, respectively. The second metal plate were a jointed plate having three layers of copper-molybdenum-copper. In comparison examples, two different kinds of metal plates were used, but each of them was made from a single material. More specifically, one metal plate was fabricated from porous, copper-impregnated tungsten or Cu—W (10% copper), while the other was made from CMC (having a thickness ratio of CU, Mo, and Cu=1:1:1). A curl was measured by a tracer method-based surface roughness meter being moved on the reverse side of the metal plate along a diagonal thereof.

TABLE 1
Table 1 illustrates comparative results.

| | Embodiment | Comparison example | |
|---|---|---|---|
| | KV + CMC | Cu—W | CMC |
| Thermal resistance | 0.7 | 1 | 0.7 |
| Curl (μm) | +10 to +20 | −10 to +20 | +30 to +60 |
| Cost | 0.5 | 1 | 0.9 |

Note 1: For Cu—W, thermal resistance and cost are valued at 1.0.
Note 2: the above positive values of the curl represent a situation in which the metal plate is rendered convex toward the ceramic frame plate bonded to the metal plate.

As seen from Table 1, the jointed metal plate in the high-frequency ceramic package according to the present invention exhibits a smaller thermal resistance value with reference to 1.0 or a Cu—W thermal resistance value in the comparison example. More specifically, it amounts to 70% of the Cu—W thermal resistance value in the comparison example. Consequently, the ceramic package according to the present invention is possible to ensure a high level of heat-sinking ability. The jointed metal plate according to the present invention produces a curl somewhat greater in positive value than a Cu—W curl in the comparison example. In other word, the jointed metal plate according to the present invention has the curl made convex toward the ceramic frame plate to a greater degree than the Cu—W curl in the comparison example. However, such a greater curl is of insignificant importance in view of availability of the high-frequency ceramic package according to the present invention. In addition, although there are variations in the curl of the jointed metal plate according to the present invention, the degree of such curl variations is smaller than that of CMC curl variations in the comparison example. Furthermore, the jointed metal plate according to the present invention costs a half of Cu—W in the comparison example with respect to 1.0 or a Cu—W cost value, and further costs less than CMC in the comparison example.

Although the embodiment of the present invention has been described, the present invention is not limited thereto, but is susceptible to other embodiments or variations encompassed within the claims.

For example, although the first metal plate fabricated from either KV or the 42-alloy has been described in the embodiment, the first metal plate is not limited in material to KV and the 42-alloy. More specifically, any metal plate close to ceramics in thermal expansion coefficient is acceptable.

What is claimed is:

1. A high-frequency ceramic package, comprising;
a first metal plate forming a substantially rectangular shape, said first metal having fixing cutouts defined at both ends in a longitudinal direction thereof and further having a hollowed portion formed at a central portion thereof,
a second metal plate being fitted in said hollowed portion of said first metal plate in a state in which said first and second metal plates are jointed in a end to end relationship, and
a ceramic frame plate brazed to a jointed metal plate on a peripheral surface of said jointed metal plate, said jointed metal plate including said first and second metal plates,
wherein a cavity defined between said second metal plate and said ceramic frame plate has a semiconductor electronic component mounting portion on a bottom of said cavity, said first metal being close to said ceramic frame plate in thermal expansion coefficient, said second metal plate being made from a material having an elevated degree of heat-sinking characteristics.

2. A high-frequency ceramic package as defined in claim 1, wherein said ceramic frame plate is brazed to said first and second metal plates in a state of being disposed across respective surfaces of said first and second metal plates along portion where said first and second metal plates are jointed together.

3. A high-frequency ceramic package as a defined in claim 1, wherein said ceramic frame plate is brazed to said first metal plate.

4. A high-frequency ceramic package as defined in claim 1, wherein said first metal plate is made from one of KV and 42 alloy, said second metal plate being made from a jointed plate having three layers of Copper-Molybdenum-Copper.
